(19) United States
(12) Patent Application Publication
(10) Pub. No.: US 2025/0120136 A1
(43) Pub. Date: Apr. 10, 2025

(54) SILICON CARBIDE SEMICONDUCTOR DEVICE

(71) Applicant: FUJI ELECTRIC CO., LTD., Kawasaki-shi (JP)

(72) Inventor: Syunki NARITA, Matsumoto-city (JP)

(73) Assignee: FUJI ELECTRIC CO., LTD., Kawasaki-shi (JP)

(21) Appl. No.: 18/889,734

(22) Filed: Sep. 19, 2024

(30) Foreign Application Priority Data
Oct. 4, 2023 (JP) 2023-173267

(51) Int. Cl. H01L 29/06; H01L 29/16; H01L 29/78

(52) U.S. Cl. CPC H10D 62/111; H10D 30/668; H10D 62/127; H10D 62/8325

(57) ABSTRACT

A silicon carbide semiconductor device, including: a semiconductor substrate; a parallel pn layer, a first semiconductor region, a plurality of second semiconductor regions, and a plurality of third semiconductor regions formed in the semiconductor substrate; a plurality of gate trenches penetrating through the first to third semiconductor regions; and a plurality of first high concentration regions. The silicon carbide semiconductor device has a double gate structure in which, for each adjacent two gate trenches, a channel is formed over an entire area of a portion of the first semiconductor region therebetween, and is sandwiched by the adjacent two gate trenches. Each first-conductivity-type region of the PN layer has a width greater than a width of each first high concentration region. Each second-conductivity-type region has a width smaller than that of each portion of the first high concentration region and greater than a distance between any adjacent two gate trenches.

### CROSS REFERENCE TO RELATED APPLICATIONS

This application is based upon and claims the benefit of priority of the prior Japanese Patent Application No. 2023-173267, filed on Oct. 4, 2023, the entire contents of which are incorporated herein by reference.

### BACKGROUND OF THE INVENTION

### 1. Field of the Invention

Embodiments of the disclosure relate to silicon carbide semiconductor device.

### 2. Description of the Related Art

F. Udrea, et al., “Experimental Demonstration, Challenges, and Prospects of the Vertical SiC FinFET”, 2022 IEEE 34th ISPSD, May 2022 and patent publication of Japanese Patent No. 6631632 describe a vertical SiC-metal oxide semiconductor field effect transistor (MOSFET) (a MOS type field effect transistor with an insulated gate having a three-layer structure of metal-oxide-semiconductor) having a trench gate structure in which a unit cell (functional unit of a device) of a FinFET structure is disposed. Japanese Laid-Open Patent Publication No. 2020-096086 and Japanese Laid-Open Patent Publication No. 2019-016775 describe that on-resistance is reduced by forming at least a part of a drift layer into a super junction (SJ) structure in which n-type regions and p-type regions are disposed repeatedly alternating with one another.

### SUMMARY OF THE INVENTION

According to an embodiment of the disclosure, a silicon carbide semiconductor device includes: a semiconductor substrate containing silicon carbide, and having a first main surface and a second main surface opposite to each other; a parallel pn layer provided in the semiconductor substrate, the parallel pn layer having a plurality of first-conductivity-type regions of a first conductivity type and a plurality of second-conductivity-type regions of a second conductivity type, disposed repeatedly alternating with each other; a first semiconductor region of the second conductivity type, provided in the semiconductor substrate between the first main surface of the semiconductor substrate and the parallel pn layer; a plurality of second semiconductor regions of the first conductivity type, selectively provided in the semiconductor substrate between the first main surface of the semiconductor substrate and the first semiconductor region; a plurality of third semiconductor regions of the second conductivity type, selectively disposed in the semiconductor substrate between the first main surface of the semiconductor substrate and the first semiconductor region, and having a dopant concentration higher than a dopant concentration of the first semiconductor region; a plurality of gate trenches penetrating, in a depth direction of the silicon carbide semiconductor device, the plurality of third semiconductor regions, the plurality of second semiconductor regions, and the first semiconductor region; a first high concentration region of the second conductivity type, provided between the first semiconductor region and the parallel pn layer and having a dopant concentration higher than the dopant concentration of the first semiconductor region, the first high concentration region having a plurality of portions selectively disposed in contact with the parallel pn layer at positions respectively facing bottoms of the plurality of gate trenches; a plurality of gate electrodes provided in the plurality of gate trenches via a plurality of gate insulating films, respectively; a first electrode electrically connected to the plurality of third semiconductor regions, the plurality of second semiconductor regions, the first semiconductor region, and the first high concentration region; and a second electrode provided at the second main surface of the semiconductor substrate. The plurality of gate trenches have, between any adjacent two thereof, a portion of the first semiconductor region therein. The silicon carbide semiconductor device has a double gate structure in which, for each adjacent two of the plurality of gate trenches, a channel is formed over an entire area of the portion of the first semiconductor region therebetween, and is sandwiched by said each adjacent two of the plurality of gate trenches. Each of the plurality of first-conductivity-type regions has a width greater than a width of each of the plurality of portions of the first high concentration region. Each of the plurality of second-conductivity-type regions has a width smaller than the width of each of the plurality of portions of the first high concentration region and greater than a distance between any adjacent two of the plurality of gate trenches.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a plan view depicting a layout of a silicon carbide semiconductor device according to a first embodiment, as viewed from a front surface of a semiconductor substrate thereof.

FIG. 2 is a cross-sectional view depicting a structure along cutting line A-A′ in FIG. 1.

FIG. 3 is a cross-sectional view depicting the structure along cutting line B-B′ in FIG. 1.

FIG. 4 is a cross-sectional view depicting a structure of a silicon carbide semiconductor device according to a second embodiment.

FIG. 5 is a cross-sectional view depicting the structure of the silicon carbide semiconductor device according to the second embodiment.

FIG. 6 is a cross-sectional view depicting the structure of the silicon carbide semiconductor device according to the second embodiment.

FIG. 7 is a cross-sectional view depicting a structure of a silicon carbide semiconductor device according to a third embodiment.

FIG. 8 is a cross-sectional view depicting the structure of the silicon carbide semiconductor device according to the third embodiment.

FIG. 9 is a cross-sectional view depicting the structure of the silicon carbide semiconductor device according to the third embodiment.

FIG. 10 is a cross-sectional view depicting a structure of a comparison example.

FIG. 11 is a characteristic diagram depicting results of verifying on- resistance characteristics of the comparison example.

FIG. 12 is a plan view depicting a layout of a silicon carbide semiconductor device of a reference example as viewed from a front surface of a semiconductor substrate thereof.

FIG. 13 is a cross-sectional view depicting a structure along cutting line AA-AA′ in FIG. 12.

FIG. 14 is a cross-sectional view depicting the structure along cutting line BB-BB′ in FIG. 12.

### DETAILED DESCRIPTION OF THE INVENTION

First problems associated with the conventional techniques are discussed. In F. Udrea, et al and patent publication of Japanese Patent No. 6631632, drift resistance, which is another resistance component of the on-resistance, becomes dominant as a breakdown voltage class increases, and the on-resistance is difficult to reduce even when a Fin width (the width between gate trenches adjacent to each other) is narrowed. F. Udrea, et al, discloses that this problem becomes prominent at breakdown voltages of 1 kV or higher (especially with a 3.3 kV class).

An outline of an embodiment of the present disclosure is described. (1) A silicon carbide semiconductor device according to one aspect of the present disclosure is as follows. In a semiconductor substrate containing silicon carbide, a parallel pn layer is provided having a plurality of first-conductivity-type regions of a first conductivity type and a plurality of second-conductivity-type regions of a second conductivity type, disposed repeatedly alternating with one another. A first semiconductor region of the second conductivity type is provided between a first main surface of the semiconductor substrate and the parallel pn layer. A plurality of second semiconductor regions of the first conductivity type is selectively provided between the first main surface of the semiconductor substrate and the first semiconductor region. A plurality of third semiconductor regions of the second conductivity type is selectively disposed between the first main surface of the semiconductor substrate and the first semiconductor region. The plurality of third semiconductor regions has a dopant concentration higher than a dopant concentration of the first semiconductor region. A plurality of gate trenches penetrates, in a depth direction, the plurality of third semiconductor regions, the plurality of second semiconductor regions, and the first semiconductor region.

A first high concentration region of the second conductivity type is provided between the first semiconductor region and the parallel pn layer and has a dopant concentration higher than the dopant concentration of the first semiconductor region. The first high concentration region has a plurality of portions each selectively disposed in contact with the parallel pn layer at a position facing a bottom of a corresponding one of the plurality of gate trenches. A plurality of gate electrodes is provided in the plurality of gate trenches via a plurality of gate insulating films, respectively. A first electrode is electrically connected to the plurality of third semiconductor regions, the plurality of second semiconductor regions, the first semiconductor region, and the first high concentration region. A second electrode is provided at a second main surface of the semiconductor substrate. The silicon carbide semiconductor device has a double gate structure in which a channel sandwiched from both side surfaces thereof by any adjacent two of the plurality of gate trenches is formed over an entire area of the first semiconductor region between the any adjacent two of the plurality of gate trenches. Each of the plurality of first-conductivity-type regions has a width greater than a width of each of the plurality of portions of the first high concentration region. Each of the plurality of second-conductivity-type regions has a width smaller than the width of the each of the plurality of portions of the first high concentration region and greater than a distance between the any adjacent two of the plurality of gate trenches.

According to the disclosure described above, the JFET resistance may be reduced by reducing carrier spreading resistance in a second direction, whereby the on-resistance may be reduced.

(2) In the silicon carbide semiconductor device according to the disclosure, in (1) above, the plurality of gate trenches extends linearly in a first direction parallel to the first main surface of the semiconductor substrate with said gate trenches being arranged adjacent to one another in a second direction parallel to the first main surface of the semiconductor substrate and orthogonal to the first direction, in a striped pattern. The plurality of first-conductivity-type regions and the plurality of second-conductivity-type regions may extend linearly in the first direction and repeatedly alternate with one another in the second direction.

According to the above disclosure, the plurality of second-conductivity-type regions reduces the carrier spreading resistance in the second direction, thereby reducing the JFET resistance.

(3) In the silicon carbide semiconductor device according to the disclosure, in (2) above, the plurality of second-conductivity-type regions may face a bottom of every other one of the plurality of gate trenches adjacent to each other in the second direction.

According to the above-mentioned disclosure, blockage of a current path due to misalignment, in the second direction, of the second-conductivity-type regions formed by ion implantation may be prevented.

(4) In the silicon carbide semiconductor device according to the disclosure, in (1) above, the plurality of gate trenches extends linearly in a first direction parallel to the first main surface of the semiconductor substrate with said gate trenches being arranged adjacent to one another in a second direction parallel to the first main surface of the semiconductor substrate and orthogonal to the first direction, in a striped pattern. The plurality of first-conductivity-type regions and the plurality of second-conductivity-type regions may extend linearly in the second direction and repeatedly alternate with one another in the first direction.

According to the disclosure, forward voltage of a body diode is reduced and the body diode is less likely to operate, thereby suppressing parasitic BJT operation.

(5) In the silicon carbide semiconductor device according to the disclosure, in (4) above, the plurality of second semiconductor regions and the plurality of third semiconductor regions repeatedly alternate with one another in the first direction. The first high concentration region has a plurality of connection portions connecting the plurality of portions facing the bottoms of the plurality of gate trenches adjacent to one another, the plurality of connection portions connecting the plurality of portions at positions facing the plurality of third semiconductor regions in the depth direction. The plurality of second-conductivity-type regions may be adjacent to the plurality of connection portions in the depth direction and may extend linearly in the second direction.

According to the disclosure described above, blockage of the current path due to misalignment, in the second direction, of the second-conductivity-type regions formed by ion implantation may be prevented.

(6) In the silicon carbide semiconductor device according to the disclosure, in (4) above, the plurality of second semiconductor regions and the plurality of third semiconductor regions repeatedly alternate with one another in the first direction. The first high concentration region has a plurality of connection portions connecting the plurality of portions facing the bottoms of the plurality of gate trenches adjacent to one another, the plurality of connection portions connecting the plurality of portions at positions facing the plurality of second semiconductor regions in the depth direction. The plurality of second-conductivity-type regions may be adjacent to the plurality of connection portions in the depth direction and may extend linearly in the second direction.

According to the disclosure described above, blockage of the current path due to misalignment, in the second direction, of the second-conductivity-type regions formed by ion implantation may be prevented.

(7) In the silicon carbide semiconductor device according to the present disclosure, in any one of (1) to (6) above, the thickness of the parallel pn layer may be 2 μm or more.

According to the disclosure, an effect of reducing the on-resistance may be further obtained.

(8) In the silicon carbide semiconductor device according to the disclosure, in any one of (1) to (7) above, the thickness of the parallel pn layer may be at least four times a thickness of the first high concentration region.

According to the disclosure, the effect of reducing the on-resistance may be further obtained.

(9) In the silicon carbide semiconductor device according to the disclosure, in any one of (1) to (8) above, the silicon carbide semiconductor device according to the present disclosure further includes a fourth semiconductor region of the first conductivity type, provided between the first semiconductor region and the parallel pn layer, the fourth semiconductor region being in contact with the first semiconductor region and the first high concentration region and having a dopant concentration at least equal to a dopant concentration of the first-conductivity-type regions. The fourth semiconductor region may terminate at a same depth toward the second electrode as a depth of the first high concentration region.

According to the disclosure, the carrier spreading resistance may be reduced.

(10) In the silicon carbide semiconductor device according to the disclosure, in any one of (1) to (9) above, the first high concentration region has a plurality of connection portions connecting the plurality of portions facing the bottoms of the plurality of gate trenches, the plurality of connection portions connecting the plurality of portions at positions between the any adjacent two of the plurality of gate trenches. The silicon carbide semiconductor device may have a second high concentration region of the second conductivity type, selectively provided between the any adjacent two of the plurality of trenches, the second high concentration region being between and in contact with the first semiconductor region and any one of the plurality of connection portions of the first high concentration region, the second high concentration region having a dopant concentration higher than a dopant concentration of the plurality of second semiconductor regions.

According to the disclosure, the first high concentration region is connected to the first semiconductor region via the second high concentration region, whereby the width of a portion of the first high concentration region may be not more than the width of the gate trench. By making the width of the first high concentration region not more than the width of the gate trench, increases in on-resistance due to the JFET resistance may be suppressed.

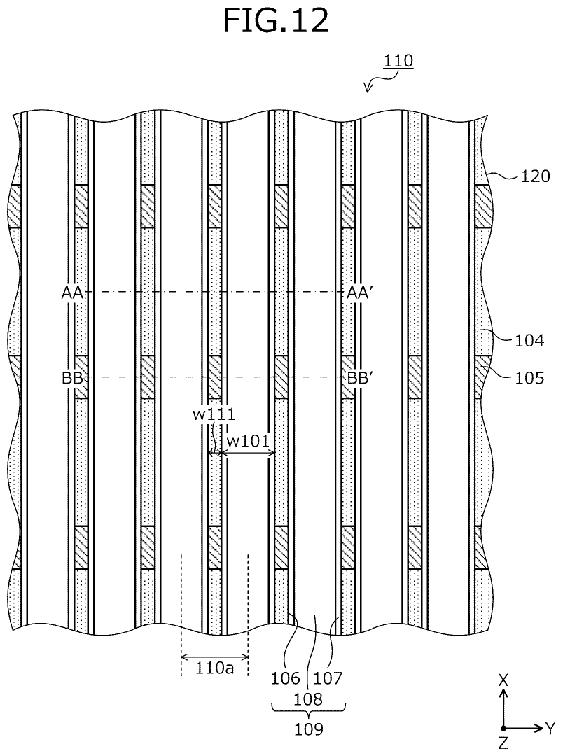

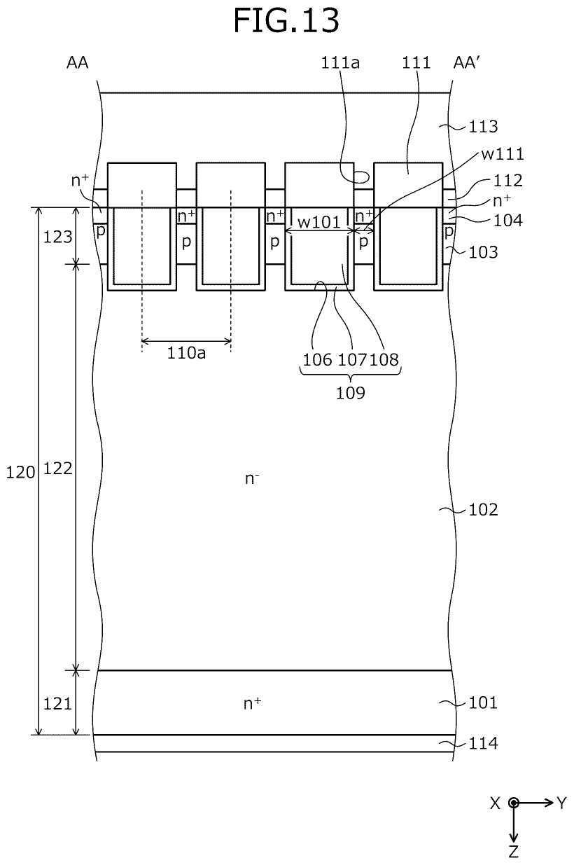

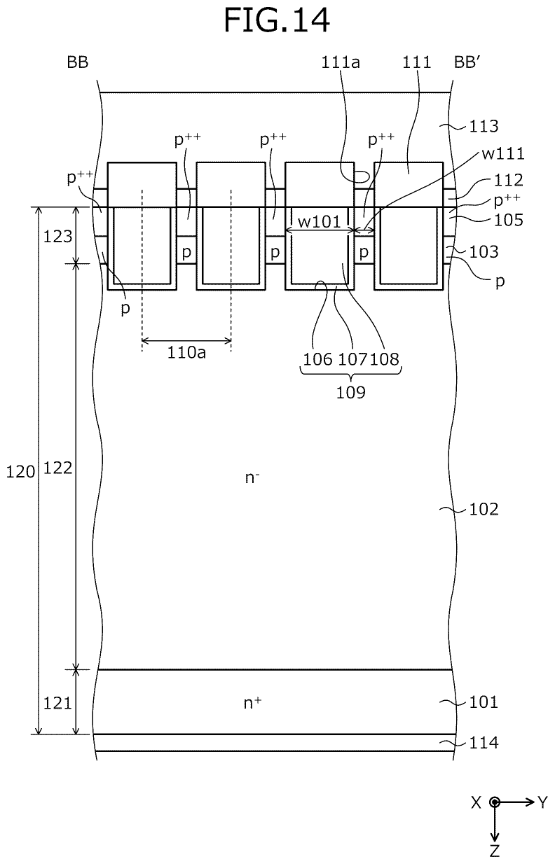

Findings underlying the present disclosure are discussed. First, a structure of a silicon carbide semiconductor device of a reference example is described. FIG. 12 is a plan view depicting a layout of the silicon carbide semiconductor device of the reference example as viewed from a front surface of a semiconductor substrate thereof. FIG. 12 depicts a layout (hatched portions) of n⁺-type source regions 104 and p⁺⁺-type contact regions 105. FIGS. 13 and 14 are cross-sectional views respectively depicting a structure along cutting lines AA-AA′ and BB-BB′ in FIG. 12. A silicon carbide semiconductor device 110 of the reference example depicted in FIGS. 12 to 14 is a vertical SiC-MOSFET with a trench gate structure having MOS gates 109 configuring a unit cell (functional unit of an element) 110a of a FinFET structure in a semiconductor substrate (semiconductor chip) 120, at a front surface (main surface on a p-type epitaxial layer 123) of the semiconductor substrate 120 containing SiC.

The semiconductor substrate 120 is formed by growing, on an n⁺-type starting substrate 121 containing SiC, epitaxial layers 122 and 123, in this order, the epitaxial layers 122 and 123 constituting an n-type drift region 102 and p-type base regions 103. The n⁺-type starting substrate 121 is an n⁺-type drain region 101. The trench gate structure is configured by the p-type base regions 103, n⁺-type source regions 104, p⁺⁺-type contact regions 105, and MOS gates 109. Each of the MOS gates 109 is configured by a gate trench 106, a gate insulating film 107, and a gate electrode 108. Each gate trench 106 has a predetermined width w101 and extends linearly in a first direction X parallel to the front surface of the semiconductor substrate 120, in a stripe-shape.

A region between centers of any adjacent two of the gate trenches 106 constitutes one unit cell 110a. A width (distance) (Fin width) w111 between the gate trenches 106 that are adjacent to one another is set narrow so that one channel (n-type inversion layer) is formed in nearly an entire area of each of the p-type base regions 103 between the gate trenches 106 that are adjacent to one another. This one channel formed between the gate trenches 106 that are adjacent to one another is in contact with different MOS gates 109 on both sides in a second direction Y, which is parallel to the front surface of the semiconductor substrate 120 and orthogonal to the first direction X. The gate trenches 106 penetrate through the p⁻-type epitaxial layer 123 from the front surface of the semiconductor substrate 120 in a depth direction Z and terminate the n⁻-type epitaxial layer 122 (n⁻-type drift region 102).

The gate electrodes 108 are disposed in the gate trenches 106 via the gate insulating films 107. A portion of the p-type epitaxial layer 123 excluding the n⁺-type source regions 104 and the p⁺⁺-type contact regions 105 formed by ion implantation in the p-type epitaxial layer 123 constitutes the p-type base regions 103. The n⁺-type source regions 104 and the p⁺⁺-type contact regions 105 are selectively disposed between the front surface of the semiconductor substrate 120 and the p-type base regions 103 and are in contact with the p-type base regions 103. The n⁺-type source regions 104 and the p⁺⁺-type contact regions 105 are provided between the gate trenches 106 that are adjacent to one another, the n⁺-type source regions 104 and the p⁺⁺-type contact regions 105 being adjacent to one another and repeatedly alternating with one another in the first direction X.

The n⁻-type drift region 102, the p-type base regions 103, the n⁺-type source regions 104, and the p⁺⁺-type contact regions 105 are in contact with the gate insulating films 107 along sidewalls of both gate trenches 106 disposed respectively on both sides in the second direction Y. The n⁻-type drift region 102 borders the bottoms of the gate trenches 106 and is in contact with the gate insulating films 107 at the bottom of the gate trenches 106. An interlayer insulating film 111 is disposed over the entire front surface of the semiconductor substrate 120 and covers the gate electrodes 108. Contact electrodes 112 are disposed on the front surface of the semiconductor substrate 120 inside contact holes 111a of the interlayer insulating film 111 and are in ohmic contact with the n⁺-type source regions 104 and the p⁺⁺-type contact regions 105.

A front electrode 113 is disposed on the interlayer insulating film 111 and the contact electrodes 112 so as to be embedded in the contact holes 111a of the interlayer insulating film 111. The front electrode 113 is electrically connected to the n⁺-type source regions 104 and the p⁺⁺-type contact regions 105 via the contact electrodes 112. The front electrode 113 and the contact electrodes 112 function as a source electrode. A back electrode 114 is disposed on an entire back surface of the semiconductor substrate 120. The back electrode 114 is in contact with and electrically connected to the n⁺-type drain region 101 (n⁺-type starting substrate 121). The back electrode 114 functions as a drain electrode.

In the silicon carbide semiconductor device 110 of the reference example described above, in F. Udrea, et al. and Japanese Laid-Open Patent Publication No. 6631632, while channel resistance is reduced by the FinFET structure and the on-resistance is reduced, the higher is the breakdown voltage class, the more dominant the drift resistance (resistance component due to the n-type drift region 102), which is another resistance component of the on-resistance, becomes and even when a Fin width w11 is reduced, the on-resistance is not easily reduced. Therefore, reduction of the on-resistance in a silicon carbide semiconductor device having a trench gate structure in which a unit cell of a FinFET structure is disposed may given as one problem to be solved in the present embodiment.

Embodiments of a silicon carbide semiconductor device according to the present disclosure are described in detail with reference to the accompanying drawings. In the present description and accompanying drawings, layers and regions prefixed with n or p mean that majority carriers are electrons or holes. Additionally, + or − appended to n or p means that the dopant concentration is higher or lower, respectively, than layers and regions without + or −. In the description of the embodiments below and the accompanying drawings, main portions that are identical are given the same reference numerals and are not repeatedly described.

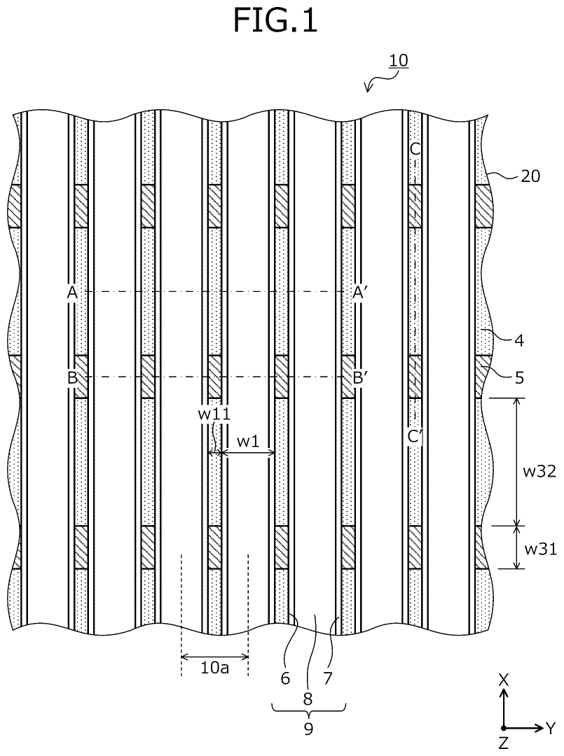

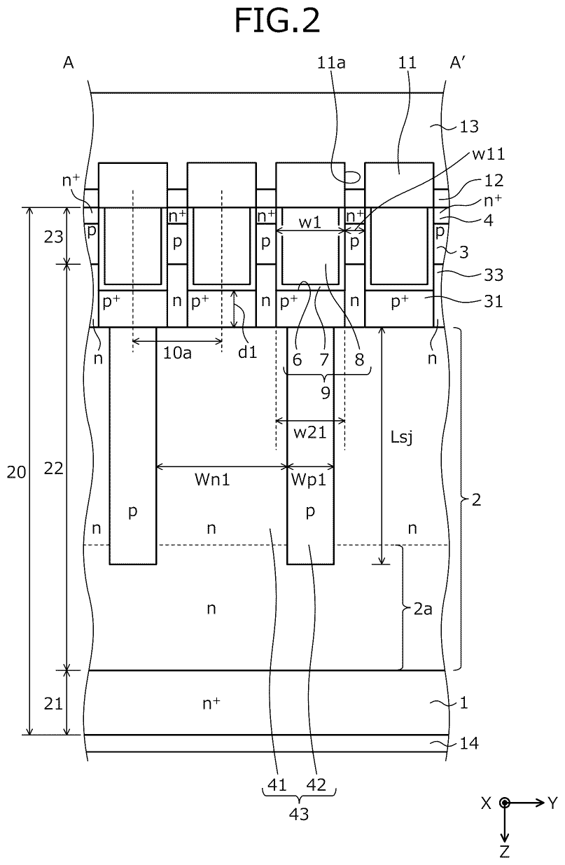

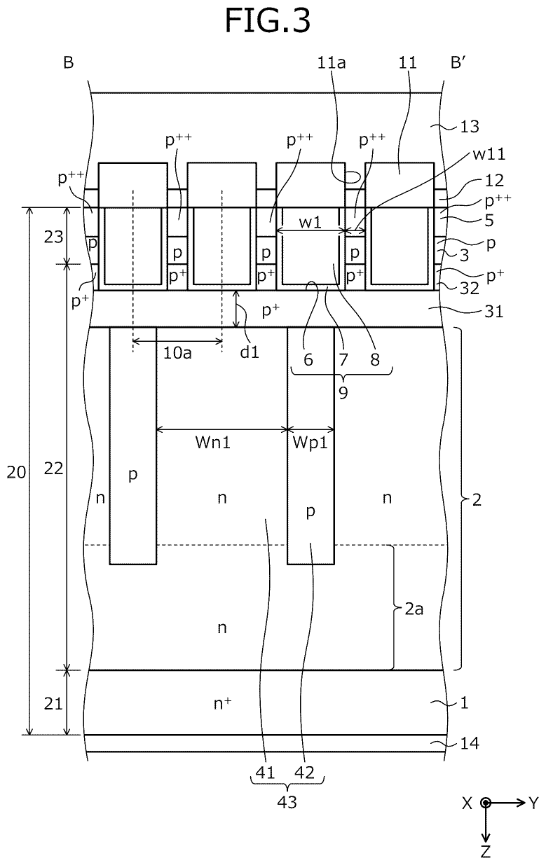

A silicon carbide semiconductor device according to a first embodiment for solving the problems mentioned above is described below. FIG. 1 is a plan view depicting a layout of the silicon carbide semiconductor device according to the first embodiment, as viewed from a front surface of a semiconductor substrate thereof. FIG. 1 depicts a layout of n⁺-type source regions 4 and p⁺⁺-type contact regions 5 (hatched portions). FIGS. 2 and 3 are cross-sectional views respectively depicting the structure along cutting lines A-A′ and B-B′ in FIG. 1.

A silicon carbide semiconductor device 10 according to the first embodiment depicted in FIGS. 1 to 3 is a vertical MOSFET with a superjunction (SJ) structure in which a drift layer (drift region) 2 has a parallel pn layer 43, the vertical MOSFET further having a trench gate structure with MOS gates 9 each configuring a unit cell (functional unit of a device) 10a of a FinFET structure in a semiconductor substrate (semiconductor chip) 20, at a front surface of the semiconductor substrate 20, which contains silicon carbide (SiC).

The semiconductor substrate 20 is formed by growing, in this order, epitaxial layers 22 and 23 constituting, respectively, a drift layer 2 and a p-type base region (first semiconductor region) 3, on a front surface of an n⁺-type starting substrate 21 that contains SiC. The semiconductor substrate 20 has, as the front surface, a first main surface on the p-type epitaxial layer 23 and has, as a back surface, a second main surface (a back surface of the n⁺-type starting substrate 21) on the n⁺-type starting substrate 21.

The drift layer 2 is in contact with an n⁺-type drain region 1 between the p-type base region 3 and the n⁺-type drain region 1. A portion of the drift layer 2, at least a portion facing n⁺-type source regions 4 described later (front side of the semiconductor substrate 20), constitutes the parallel pn layer 43. In the parallel pn layer 43, n-type regions (hereinafter referred to as n-type column regions (first-conductivity-type regions) 41 and p-type regions (hereinafter referred to as p-type column regions (second-conductivity-type regions) 42 are disposed adjacent to and repeatedly alternating with one another in a direction parallel to the front surface of the semiconductor substrate 20.

The n-type column regions 41 and the p-type column regions 42 are arranged in a striped pattern extending linearly in a direction orthogonal to the direction in which the n-type column regions 41 and the p-type column regions 42 are adjacent to each other as viewed from the front surface of the semiconductor substrate 20. The n-type column regions 41 and the p-type column regions 42 extend linearly from a boundary with n-type current spreading regions 33 described later in a direction to the n⁺-type drain region 1 (back surface of the semiconductor substrate 20), contacting the n⁺-type drain region 1.

In the first embodiment, a lateral direction of the n-type column regions 41 and the p-type column regions 42 is the same as a lateral direction (second direction Y) of gate trenches 6 described later. A longitudinal direction of the n-type column regions 41 and the p-type column regions 42, as viewed from the front surface of the semiconductor substrate 20, is the same as the longitudinal direction (first direction X) of the gate trenches 6. The n-type column regions 41 and the p-type column regions 42 respectively face different gate trenches 6 in a depth direction Z.

A portion of the drift layer 2 between the parallel pn layer 43 and the n⁺-type drain region 1 may be an n-type buffer region (n-type region free of the SJ structure) 2a. A dopant concentration of the n-type buffer region 2a is not more than a dopant concentration of the n-type column regions 41. In a case in which the n-type buffer region 2a is disposed, the n-type column regions 41 and the p-type column regions 42, at respective ends thereof facing the n⁺-type drain region 1, are in contact with the n-type buffer region 2a and the n-type buffer region 2a is in contact with the n⁺-type drain region 1.

A thickness Lsj of the parallel pn layer 43 is determined by a thickness of the p-type column regions 42. In a case in which the n-type buffer region 2a is disposed, the p-type column regions 42 may reach a deeper position toward the n⁺-type drain region 1 than are the n-type column regions 41. In this case, the n-type buffer region 2a extends in between the p-type column regions 42 adjacent to each other, in a direction from the n⁺-type drain region 1. The portions of the n-type buffer region 2a extending between the p-type column regions 42 adjacent to each other function as the parallel pn layer 43.

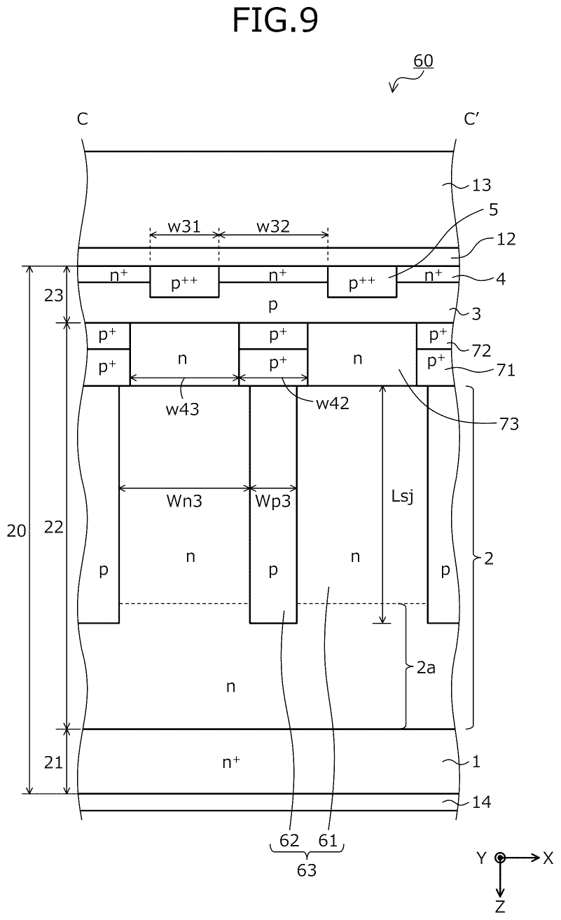

An effect of the parallel pn layer 43 may be obtained by setting the thickness Lsj of the parallel pn layer 43 to about 2 μm or more (see FIG. 9). The thickness Lsj of the parallel pn layer 43 may be preferably, for example, about at least four times a depth d1 of a first p⁺-type region 31 described later. The depth d1 of the first p⁺-type region 31 is a length in the depth direction Z from a bottom of any one of the gate trenches 6 to the parallel pn layer 43 and corresponds to a thickness of the first p⁺-type region 31, and is, for example, about 0.5 μm.

Respective widths (widths in the lateral direction) Wn1 and Wp1 of the n-type column regions 41 and the p-type column regions 42 are substantially uniform in the depth direction Z. Respective dopant concentrations of the n-type column regions 41 and the p-type column regions 42 are, for example, substantially uniform in the depth direction Z. Balance charge is generally maintained between the n-type column regions 41 and the p-type column regions 42 adjacent to each other. A drift resistance (resistance component due to the drift layer 2) may be adjusted by the dopant concentration of the n-type column regions 41.

The width and dopant concentration being substantially uniform means that the width is the same within a range that includes an allowable error due to process variation and the dopant concentration is the same within a range that includes an allowable error due to process variation. Balanced charge is an index that indicates the degree of balance between a charge amount represented by a product of the carrier concentration (concentration of activated dopants) of the n-type column regions 41 and the width Wn1 of each of the n-type column regions 41 in a lateral direction, and a charge amount represented by a product of the carrier concentration of the p-type column regions 42 and Wp1 that is the width in the lateral direction.

The width Wn1 that is the width of each of the n-type column regions 41 in the lateral direction (here, referred to the second direction Y) is wider than a width w21, in the second direction Y, of each portion of the first p⁺-type region 31 directly below the gate trenches 6 (facing the n⁺-type drain region 1) (Wn1>w21). The width Wp1 of each of the p-type column regions 42 in the lateral direction (here, referred to the second direction Y) is narrower than the width w21, in the second direction Y, of each portion of the first p⁺-type region 31 directly below the gate trenches 6 and is wider than the Fin width w11 described later (w21>Wp1>w11).

By setting the respective widths Wn1 and Wp1, in the lateral direction, of the n-type column regions 41 and the p-type column regions 42 under the conditions above, the p-type column regions 42 are arranged directly below every other one the gate trenches 6 (i.e., facing the bottoms of the gate trenches 6), which are arranged at a predetermined pitch in the second direction Y. The n-type column regions 41 are arranged below the gate trenches 6 excluding the gate trenches 6 that face the p-type column regions 42 in the depth direction Z. Carrier spreading resistance is reduced as compared to a case in which the p-type column regions 42 are arranged directly below all the gate trenches 6.

The widths Wn1 and Wp1, in the lateral direction, of the n-type column regions 41 and the p-type column regions 42 according to the conditions above, whereby blockage a current path (connections between the n-type current spreading regions 33 and the n-type column regions 41) due to misalignment (positional shift) of the p-type column regions 42 in the second direction Y may be prevented, the p-type column regions 42 being formed by ion implantation of a p-type dopant into the n-type epitaxial layer 22, as described below. The width Wp1 of each of the p-type column regions 42 in the second direction Y in may be narrowed only at an end thereof facing the n⁺-type source regions 4, ensuring the current path.

As the length of the p-type column regions 42 in the depth direction Z becomes closer to the thickness of the drift layer 2, on-resistance decreases, however, the length of the p-type column regions 42 in the depth direction Z increases and thus, manufacturing costs increase due to an increase in the number of stages of a multi-stage epitaxial method for forming the parallel pn layer 43. The length of the p-type column regions 42 in the depth direction Z is a distance (depth) in the depth direction Z from a boundary thereof with the first p⁺-type region 31 to a boundary thereof with the n-type buffer region 2a.

The multi-stage epitaxial method is a method in which epitaxial grow of the n-type epitaxial layer 22 is divided into multiple stages (multiple sessions) and at each stage, p-type regions that become the p-type column regions 42 are selectively formed by ion implantation of a p-type dopant so as to be adjacent to each other in the depth direction Z while n-type regions that become the n-type column regions 41 remain in the n-type epitaxial layer 22 at each stage.

By forming the drift layer 2 as an SJ structure using the parallel pn layers 43, a dopant concentration of the n-type column regions 41 acting as a current path of a main current (drift current) of the SiC-MOSFET may be increased as compared to a case in which the drift layer is formed as the n-type drift region 102 which does not have the SJ structure as in the reference structure (see FIGS. 12 to 14). The higher is the dopant concentration of the n-type column regions 41, the greater the drift resistance may be reduced, whereby the on-resistance is reduced.

The trench gate structure is configured by the p-type base region 3, the n⁺-type source regions (second semiconductor regions) 4, the p⁺⁺-type contact regions (plurality of third semiconductor regions) 5, and the MOS gates 9. The MOS gates 9 are configured by the gate trenches 6, gate insulating films 7, and gate electrodes 8. The gate trenches 6 penetrate through the p-type epitaxial layer 23 from the front surface of the semiconductor substrate 20 in the depth direction Z and reach the first p⁺-type region 31 described later. In a cross-sectional view, the gate trenches 6 have, for example, a substantially rectangular shape.

The gate trenches 6 extend linearly in the first direction X, which is parallel to the front surface of the semiconductor substrate 20, and are adjacent to one another in the second direction Y, which is parallel to the front surface of the semiconductor substrate 20 and orthogonal to the first direction X. That is, the gate trenches 6 are arranged in the striped pattern extending in the first direction X, as viewed from the front surface of the semiconductor substrate 20. The width w1 of each of the gate trenches 6 in the second direction Y is uniform over an entire area thereof in the first direction X.

The width w11 (hereinafter referred to as the Fin width) between any adjacent two of the gate trenches 6 is uniform over an entire area thereof in the first direction X. The Fin width w11 is narrower than the width w1 of each of the gate trenches 6 in the second direction Y (w11<w1) and is not more than about 200 nm, for example, about 100 nm. The area between centers of any adjacent two of the gate trenches 6 constitutes one unit cell 10a of the FinFET structure.

Multiple unit cells 10a each having a same structure are arranged adjacent to one another in the second direction Y (the lateral direction of the gate trenches 6). The FinFET structure is a so-called double gate structure in which the width (Fin width) w11 between the gate trenches 6 adjacent to each other is narrowed by the predetermined width and one channel (n-type inversion layer) formed in nearly an entire area of the p-type base region 3 between any adjacent two of the gate trenches 6 is sandwiched on both sides thereof by the MOS gates 9.

The Fin width w11 is reduced to form the FinFET structure, thereby reducing the electric field in a direction parallel to the front surface of the semiconductor substrate 20, in the vicinity of the bottoms of the gate trenches 6. Thus, carrier spreading in the vicinity of the bottoms of the gate trenches 6 is reduced and the mobility of carriers is improved, thereby lowering channel resistance and reducing the on-resistance. The gate electrodes 8 are provided inside the gate trenches 6 via the gate insulating films 7, respectively.

The n⁺-type source regions 4 and the p⁺⁺-type contact regions 5 are selectively provided between the front surface of the semiconductor substrate 20 and the p-type base region 3, the n⁺-type source regions 4 and the p⁺⁺-type contact regions 5 being in contact with the p-type base region 3 and in ohmic contact with later-described contact electrodes 12 on the front surface of the semiconductor substrate 20. The n⁺-type source regions 4 and the p⁺⁺-type contact regions 5 are provided adjacent to one another and repeatedly alternate with one another in the first direction X between the gate trenches 6 adjacent to each other.

The n⁺-type source regions 4 of the unit cells 10a adjacent to each other in the second direction Y face each other with the MOS gates 9 therebetween. The p⁺⁺-type contact regions 5 of the unit cells 10a adjacent to each other in the second direction Y face each other with the MOS gates 9 therebetween. A portion of the p-type epitaxial layer 23 excluding the n⁺-type source regions 4 and the p⁺⁺-type contact regions 5 that are formed in the p-type epitaxial layer 23 by ion implantation constitutes the p-type base region 3.

The n⁺-type source regions 4, the p⁺⁺-type contact regions 5, the p-type base region 3, and the n-type current spreading regions 33, at both sides of each in the second direction Y, are in contact with the gate insulating films 7 along sidewalls of both of the gate trenches 6 respectively located on said sides in the second direction Y. The first and second p⁺-type regions (first and second high concentration regions) 31, 32 and the n-type current spreading regions (fourth semiconductor regions) 33 are selectively disposed between the p-type base region 3 and the parallel pn layer 43.

A portion of the n-type epitaxial layer 22 excluding the first and second p⁺-type regions 31, 32 and the n-type current spreading regions 33 formed in the n-type epitaxial layer 22 by ion implantation constitutes the drift layer 2. The first and second p⁺-type regions 31 and 32 have a function of depleting (or depleting the n-type current spreading regions 33, or both) when the SiC-MOSFET is off, thereby relaxing the electric field applied to the gate insulating films 7.

The first p⁺-type region 31 is disposed at positions facing the bottoms of the gate trenches 6, apart from the p-type base region 3. The first p⁺-type region 31 extends in the first direction X with the predetermined width w21 and substantially a same length as a longitudinal length of the gate trenches 6. The width w21, in the second direction Y, of the portions of the first p⁺-type region 31 directly below the gate trenches 6 is not more than the width w1 of each of the gate trenches 6 in the second direction Y and is wider than the Fin width w11.

The portions of the first p⁺-type regions 31 directly below the gate trenches 6 adjacent to each other extend to directly below the p⁺⁺-type contact regions 5 and are partially connected to each other. The first p⁺-type region 31 is not disposed directly below the n⁺-type source regions 4. That is, the first p⁺-type region 31 is disposed facing the bottoms of the gate trenches 6 and the p⁺⁺-type contact regions 5 in the depth direction Z, in a ladder shape (lattice shape) as viewed from the front surface of the semiconductor substrate 20.

The first p⁺-type region 31 has an upper surface (surface facing the n⁺-type source regions 4) in contact with the second p⁺-type regions 32 and the gate insulating films 7 along the bottoms of the gate trenches 6. The portions of the first p⁺-type region 31, respectively, directly below the gate trenches 6 each have a lower surface (surface facing the n⁺-type drain region 1) in contact with different one of the column regions (the n-type column regions 41, the p-type column regions 42) of the parallel pn layer 43. Portions of the first p⁺-type region 31 directly below the p⁺⁺-type contact regions 5 are in contact with the n-type column regions 41 in the depth direction Z.

A width, in the first direction X, of the portions of the first p⁺-type region 31, respectively, directly below the p⁺⁺-type contact regions 5 is, for example, substantially a same as a width w31 of each of the p⁺⁺-type contact regions 5 in the first direction X. An interval at which the portions of the first p⁺-type region 31 directly below the p⁺⁺-type contact regions 5 disposed in the first direction X is, for example, substantially a same as an interval w32 between the p⁺⁺-type contact regions 5 adjacent to each other in the first direction X. Substantially the same length, substantially the same width, and substantially the same interval respectively mean the same length, width, and interval within a range that includes an allowable error due to variation in the manufacturing process.

The second p⁺-type regions 32 are provided between and in contact with the p-type base region 3 and the first p⁺-type region 31 (connection portion thereof between the portions of the first p⁺-type region 31 directly below the gate trenches 6 adjacent to each other). The second p⁺-type regions 32 are in contact with the gate insulating films 7 along the sidewalls of both of the gate trenches 6 respectively located on both sides thereof in the second direction Y. The first p⁺-type region 31 is electrically connected to the p-type base region 3 by the second p⁺-type regions 32.

The second p⁺-type regions 32 are provided only directly below the p⁺⁺-type contact regions 5 and are interspersed in the first direction X. The second p⁺-type regions 32 are not disposed directly below the n⁺-type source regions 4. The width, in the first direction X, of the second p⁺-type regions 32 is, for example, substantially the same as the width w31 of the p⁺⁺-type contact regions 5 in the first direction X. The interval between second p⁺-type regions 32 adjacent to each other in the first direction X is, for example, substantially the same as the interval w32 between p⁺⁺-type contact regions 5 adjacent to each other in the first direction X.

The n-type current spreading region 33 is a so-called a current spreading layer (CSL) that reduces the carrier spreading resistance. The n-type current spreading regions 33 are provided and thus, when the SiC-MOSFET is on, the electron current is easily diffused from the channel formed in the p-type base region 3 between the gate trenches 6 adjacent to each other to the n-type column regions 41, thereby reducing the on-resistance.

The n-type current spreading regions 33 each have an upper surface in contact with the p-type base region 3 and a lower surface in contact with the n-type column regions 41. The n-type current spreading regions 33 are not in contact with the p-type column regions 42. Each of the n-type current spreading regions 33, at side surfaces thereof in the first direction X, is in contact with the first and second p⁺-regions 31 and 32 and at side surfaces thereof in the second direction Y, is in contact with the gate insulating films 7 along the sidewalls of the gate trenches 6 and the first p⁺-region 31. The n-type current spreading regions 33 are provided only directly below the n⁺-source regions 4.

The n-type current spreading regions 33 terminate at substantially a same depth as the first p⁺-type region 31, toward the n⁺-type drain region 1.

That is, the n-type current spreading regions 33 are arranged in a matrix shape and bordered by the first p⁺-type region 31 at a position deeper toward the n⁺-type drain region 1 than are the bottoms of the gate trenches 6. Between the gate trenches 6 adjacent to each other, the n-type current spreading regions 33 and the second p⁺-type regions 32 are disposed adjacent to one another and repeatedly alternate with one another in the first direction X. Substantially the same depth means that the depth is the same within a range that includes an allowable error due to variation in the manufacturing process.

The dopant concentration of the n-type current spreading regions 33 is at least equal to the dopant concentration of the n-type column regions 41 and, preferably, may be higher than the dopant concentration of the n-type column regions 41. Specifically, the dopant concentration of the n-type column regions 41 is in a range of about 1.0×10¹⁶/cm³ to 1.0×10¹⁷/cm³, and the dopant concentration of the n-type current spreading regions 33 is in a range of about 3.0×10¹⁶/cm³ to 1.0×10¹⁷/cm³. Preferably, the dopant concentration of the n-type current spreading regions 33 may be in a range of about 5.0×10¹⁶/cm³ to 5.0×10¹⁷/cm³.

The n-type current spreading regions 33 may be omitted. In this case, instead of the n-type current spreading regions 33, the n-type column regions 41 reach the p-type base region 3, are in contact with the first and second p⁺-type regions 31 and 32 in the first direction X, and are in contact with the gate insulating films 7 along the sidewalls of the gate trenches 6 and the first p⁺-type region 31 in the second direction Y.

An interlayer insulating film 11 is disposed on the entire front surface of the semiconductor substrate 20 and covers the gate electrodes 8. The n⁺-type source regions 4 and the p⁺⁺-type contact regions 5 are exposed in contact holes 11a of the interlayer insulating film 11. In a cross-sectional view, the contact holes 11a may have a substantially rectangular shape or may have a tapered (trapezoidal) shape that narrows toward the front surface of the semiconductor substrate 20.

The contact electrodes 12 are embedded in the contact holes 11a and are on the front surface of the semiconductor substrate 20. The contact electrodes 12 are in ohmic contact with the n⁺-type source regions 4 and the p⁺⁺-type contact regions 5. A front electrode 13 is provided on the interlayer insulating film 11 and the contact electrodes 12 so as to be embedded in the contact holes 11a of the interlayer insulating film 11.

The front electrode 13 is electrically connected to the n⁺-type source regions 4 and the p⁺⁺-type contact regions 5 via the contact electrodes 12. The front electrode 13 and the contact electrodes 12 function as a source electrode (first electrode). A back electrode 14 is provided on the entire back surface of the semiconductor substrate 20. The back electrode 14 is in contact with and electrically connected to the n⁺-type drain region 1 (n⁺-type starting substrate 21). The back electrode 14 functions as a drain electrode (second electrode).

Operation of the silicon carbide semiconductor device 10 (SiC-MOSFET) according to the embodiments is described. When a voltage that is positive with respect to the source electrode (front electrode 13 and contact electrodes 12) is applied to the drain electrode (back electrode 14) (forward bias between the drain and source), pn junctions between the p⁺⁺-type contact regions 5, the p-type base region 3, the first and second p⁺-type regions 31 and 32, the n-type current spreading regions 33, the n-type column regions 41, and the n⁺-type drain region 1 are reverse-biased. In this state, when voltage applied to the gate electrodes 8 is less than the gate threshold voltage, the SiC-MOSFET maintains the off state.

The gate insulating films 7 along the bottoms of the gate trenches 6 are protected by the first p⁺-type region 31 and thus, the electric field applied to the gate insulating films 7 is relaxed when the SiC-MOSFET is off. A predetermined breakdown voltage is ensured by a depletion layer which spreads from main junctions when the SiC-MOSFET is off. When the SiC-MOSFET is off, pn junctions between the p-type column regions 42 and the n-type column regions 41 are reverse biased, the depletion layer spreads from the pn junctions, and the breakdown voltage is borne by the parallel pn layer 43. This ensures the predetermined breakdown voltage, which exceeds a breakdown voltage that can be achieved by the dopant concentration (n-type column regions 41) of the drift layer 2.

Meanwhile, when gate voltage at least equal to the gate threshold voltage is applied to the gate electrodes 8 in a state where the drain-source is forward biased, one channel (n-type inversion layer) is formed in contact with different ones of the MOS gates 9 (the gate insulating films 7 at the sidewalls of the gate trenches 6) on both sides of the channel in the second direction Y, over nearly an entire area, in the first direction X, of each of the p-type base regions 3 between the gate trenches 6 adjacent to each other. Thus, a drift current (main current) flows from the n⁺-type drain region 1 through the n-type column regions 41, the n-type current spreading regions 33, and the channel to the n⁺-type source regions 4, and the SiC-MOSFET turns on.

When the SiC-MOSFET is on, adverse effects of the electric field generated by the flow of the main current in the second direction Y are reduced by the FinFET structure, whereby carrier spreading is reduced, carrier mobility is improved, channel resistance is lowered, and the on-resistance is reduced. The drift layer 2 is formed as the SJ structure with the parallel pn layer 43, whereby the dopant concentration of the n-type column regions 41, which form the current path of the main current, may be increased to reduce the drift resistance. The p-type column regions 42 reduce the carrier spreading resistance in the second direction Y, thereby reducing the junction FET (JFET) resistance. As a result, the on-resistance is further reduced.

A method of manufacturing the silicon carbide semiconductor device 10 according to the first embodiment is described. First, the drift layer 2 including the parallel pn layer 43 is formed on the front surface of the n⁺-type starting substrate (n⁺-type starting wafer) 21 which constitutes the n⁺-type drain region 1. Here, for example, the multi-stage epitaxial method is used, epitaxial growth of the n-type epitaxial layer 22 which constitutes the drift layer 2 is divided into the multiple stages and at each stage, the p-type regions respectively constituting the p-type column regions 42 in each n-type epitaxial layer are selectively formed by ion implantation of a p-type dopant.

Portions of the n-type epitaxial layer 22 that are not ion-implanted and between the p-type column regions 42 adjacent to each other are left as an n-type and constitute the n-type column regions 41. A portion of the n-type epitaxial layer 22 between the parallel pn layer 43 (n-type column regions 41 and p-type column regions 42) and the n⁺-type starting substrate 21 may be left as an n-type without ion implantation, thereby forming the n-type buffer region 2a. In this case, the n-type buffer region 2a is formed having a same dopant concentration as the dopant concentration of the n-type column regions 41 (the dopant concentration of the n-type epitaxial layer 22).

The n-type column regions 41 may be formed by ion implantation of an n-type dopant. In this case, for example, instead of the n-type epitaxial layer 22, a non-doped epitaxial layer or an n-type epitaxial layer with the same dopant concentration as the n-type buffer region 2a is grown in multiple stages by epitaxy. lon implantation of the n-type dopant may be performed in the portion of the non-doped epitaxial layer constituting the n-type buffer region 2a. Thus, the n-type buffer region 2a with a dopant concentration lower than the dopant concentration of the n-type column regions 41 may be formed.

Next, epitaxy is performed to thereby increase the thickness of the n-type epitaxial layer 22. Thereafter, the first p⁺-type region 31 is selectively formed in the thickened portion of the n-type epitaxial layer 22 by ion implantation of a p-type dopant at a depth penetrating the thickened portion of the n-type epitaxial layer 22, and lower portions of the n-type current spreading regions 33 are formed by ion implantation of an n-type dopant. The first p⁺-type region 31 is disposed in a lattice shape extending linearly in the first and second directions X and Y, as viewed from the surface of the n-type epitaxial layer 22.

Portions of the first p⁺-type region 31 extending linearly in the first direction X are in contact with different column regions of the parallel pn layer 43 in the depth direction Z, while portions thereof extending linearly in the second direction Y are in contact with all column regions of the parallel pn layer 43, in the depth direction Z. The lower portions of the n-type current spreading regions 33 are arranged in a matrix shape and bordered by the first p⁺-type region 31, and are in contact with the n-type column regions 41 in the depth direction Z. Instead of increasing the thickness of the n-type epitaxial layer 22, the first p⁺-type region 31 and the lower portions of the n-type current spreading regions 33 may be formed in the parallel pn layer 43, at the surface thereof.

Thereafter, epitaxy is performed to further increase the thickness of the n-type epitaxial layer 22 to a predetermined thickness for the completed product (the silicon carbide semiconductor device 10). Next, by ion implantation of a p-type dopant, the second p⁺-type regions 32 are selectively formed to a depth so as to penetrate through the thickened portion of the n-type epitaxial layer 22, and upper portions of the n-type current spreading regions 33 are formed by ion implantation of an n-type dopant. The second p⁺-type regions 32 are arranged, for example, in a striped pattern extending in the second direction Y.

The upper portions of the n-type current spreading regions 33 are formed between the second p⁺-type regions 32 adjacent to each other and are arranged in a striped pattern extending in the second direction Y. The second p⁺-type regions 32 and the n-type current spreading regions 33 are also formed in formation regions of the gate trenches 6, but the portions thereof formed in the formation regions of the gate trenches 6 are removed when the gate trenches 6 are formed. The second p⁺-type regions 32 are connected to the first p⁺-type region 31 in the depth direction Z. The upper portions of the n-type current spreading regions 33 are connected to the lower portions of the n-type current spreading regions 33 in the depth direction Z.

The p-type epitaxial layer 23 constituting the p-type base regions 3 is grown by epitaxy on the n-type epitaxial layer 22. The p-type epitaxial layer 23 is in contact with the upper parts of the n-type current spreading regions 33 and the second p⁺-type regions 32. By the processes up to this point, the semiconductor substrate (semiconductor wafer) 20 is fabricated (manufactured) in which the epitaxial layers 22 and 23 are deposited in the order stated, on the front surface of the n⁺-type starting substrate 21.

The n⁺-type source regions 4 and the p⁺⁺-type contact regions 5 are each selectively formed in surface regions of the p-type epitaxial layer 23 by ion implantation. Portions of the p-type epitaxial layer 23 closer to the n-type epitaxial layer 22 than are the n⁺-type source regions 4 and the p⁺⁺-type contact regions 5 constitute the p-type base regions 3. A p-type dopant concentration profile contributing to the gate threshold voltage may be adjusted by ion implantation in the p-type base regions 3.

A heat treatment is performed to activate all the ion-implanted dopants. The gate trenches 6 are formed which penetrate through the n⁺-type source regions 4, the p⁺⁺-type contact regions 5, and the p-type base regions 3, and reach the first p⁺-type regions 31. The n⁺-type source regions 4, the p⁺⁺-type contact regions 5, the p-type base regions 3, the second p⁺-type regions 32, and the n-type current spreading regions 33 are exposed along the sidewalls of the gate trenches 6, and the first p⁺-type regions 31 are exposed along the bottoms of the trenches 6.

By a general method, the gate electrodes 8 are embedded in the gate trenches 6 via the gate insulating films 7, thereby forming the MOS gates 9. The interlayer insulating film 11, the contact electrodes 12, the front electrode 13, and the back electrode 14 are formed by a general method. Thereafter, the semiconductor wafer (semiconductor substrate 20) is diced (cut) into individual chips, thereby completing the silicon carbide semiconductor device 10 depicted in FIGS. 1 to 3.

As described above, according to the embodiment, the cell with the FinFET structure is disposed, the drift layer (the drift region) has the SJ structure in which the parallel pn layer is formed by the n-type column regions and the p-type column regions, and the n-type column regions and the p-type column regions are arranged in the striped shape extending parallel to a longitudinal direction (the first direction) of the trench. In addition, the width of the lateral direction in the n-type column regions is set wider than the width of the second direction in the part directly below the gate trench of the first p⁺-type region. The width of the p-type column regions in the short-side direction is set narrower than the width of the second direction of the part directly below the gate trench of the first p⁺-type region, and wider than the Fin width.

The FinFET structure reduces carrier spreading and improves carrier mobility, thereby lowering the channel resistance and reducing the on-resistance. By forming the drift layer in the SJ structure, the dopant concentration of the n-type column regions, which constitute the current path of the main current, is increased to reduce the drift resistance, and the p-type column regions reduce the carrier spreading resistance in the second direction, thereby reducing the JFET resistance. By setting the widths of the n-type column regions and the p-type column regions in the lateral direction under the above conditions, the p-type column regions are arranged directly under every other gate trench adjacent to each other in the second direction. This further reduces the carrier spreading resistance in the second direction, thereby further reducing the JFET resistance.

In a vertical MOSFET, the JFET resistance and the drift resistance account for a majority of the on-resistance. According to the first embodiment, as described above, among the multiple resistance components of the on-resistance, resistance components excluding the drift resistance (the JFET resistance) may be reduced, whereby the on-resistance may be reduced even in a high breakdown voltage class where the drift resistance is dominant. The high breakdown voltage class is, for example, a breakdown voltage class of 1 kV or more (particularly, a breakdown voltage class of 3.3 kV). According to the first embodiment, by setting the widths of the n-type column regions and the p-type column regions in the lateral directions to the above conditions, blockage of the current path due to misalignment of the p-type column regions in the second direction may be prevented, thereby preventing increases in the JFET resistance.

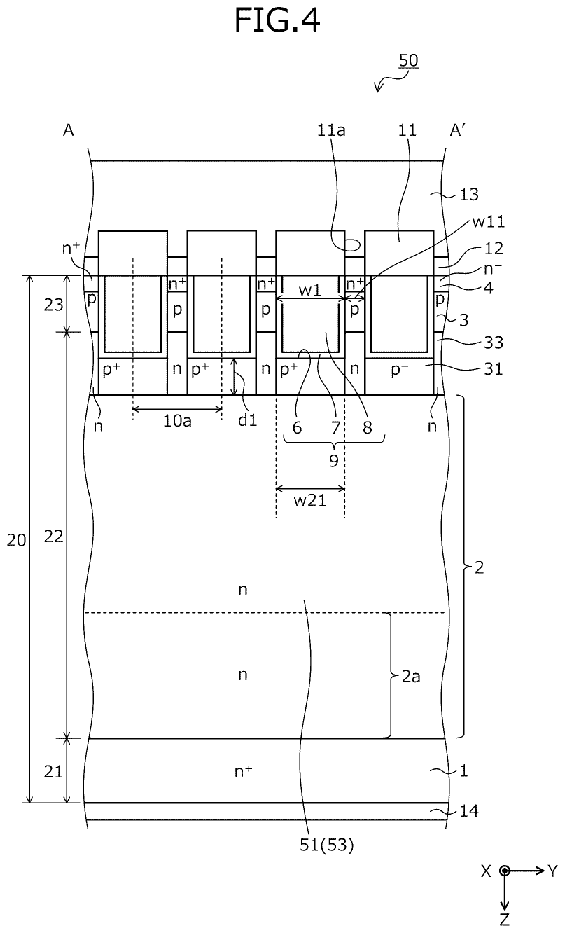

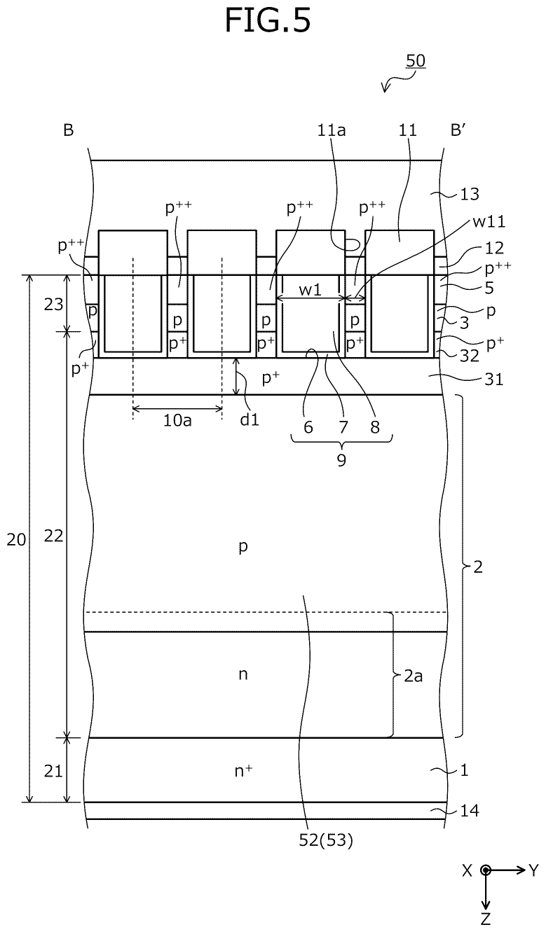

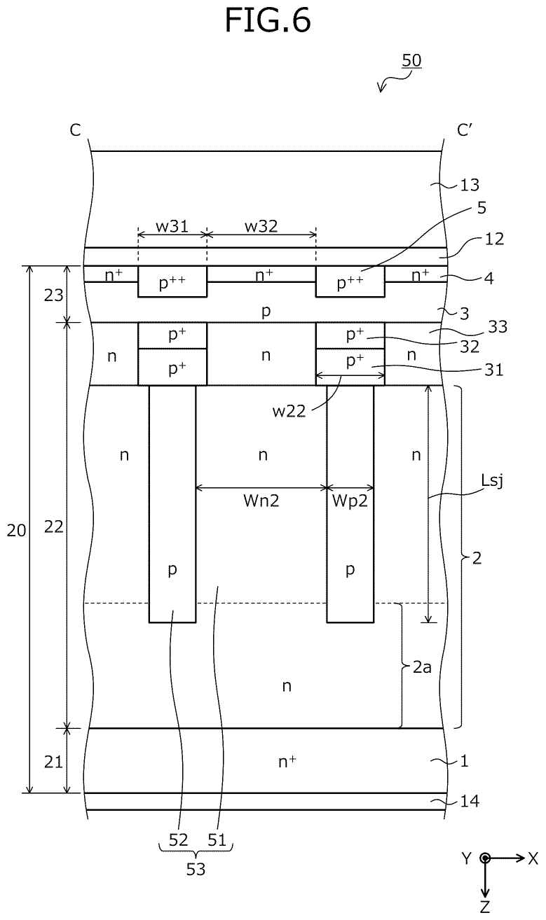

A silicon carbide semiconductor device according to a second embodiment solving the problems mentioned above is described. FIGS. 4, 5, and 6 are cross-sectional views depicting a structure of the silicon carbide semiconductor device according to the second embodiment. A layout of the n⁺-type source regions 4, the p⁺⁺-type contact regions 5, and the MOS gates 9 of a silicon carbide semiconductor device 50 according to the second embodiment as viewed from the front surface of the semiconductor substrate 20 is the same as that of the first embodiment (see FIG. 1). FIGS. 4 to 6 depict the structure along cutting lines A-A′, B-B′, and C-C′ in FIG. 1. In FIG. 5, a boundary between the n-type buffer region 2a and n-type column regions 51 is indicated by a dashed line.

The silicon carbide semiconductor device 50 according to the second embodiment differs from the silicon carbide semiconductor device 10 according to the first embodiment (see FIGS. 2 and 3) in that a longitudinal direction of the n-type column regions 51 and p-type column regions 52 of a parallel pn layer 53 is orthogonal to the longitudinal direction (the first direction X) of the gate trenches 6. Directly below the n⁺-type source regions 4, the n-type column regions 51 extend linearly in the second direction Y, in contact with the first p⁺-type region 31 and the n-type current spreading regions 33. A width Wn2 of each of the n-type column regions 51 in the lateral direction (the first direction X) is wider than a width w22 (in the first direction X) of each portion of the first p⁺-type region 31 directly below the p⁺⁺-type contact regions 5 in (Wn2>w22).

The p-type column regions 52 directly below the p⁺⁺-type contact regions 5 extend linearly in the second direction Y, in contact with only the first p⁺-type region 31. The p-type column regions 52 are not in contact with the n-type current spreading regions 33. A width Wp2 of each of the p-type column regions 52 in the lateral direction (the first direction X) is narrower than a width w41 (in the first direction X) of each of the portions of the first p⁺-type region 31 directly below the p⁺⁺-type contact regions 5, and is wider than the Fin width w11 (w22>Wp2>w11). Directly below the p⁺⁺-type contact regions 5, the p-type column regions 52 extend linearly in the second direction Y, whereby blockage of the current path (the connection between the n-type current spreading regions 33 and the n-type column regions 41) due to misalignment of the p-type column regions 52 in the second direction Y.

The respective widths Wn2 and Wp2 of the n-type column regions 51 and the p-type column regions 52 in the lateral direction are substantially uniform in the depth direction Z. Respective dopant concentrations of the n-type column regions 51 and the p-type column regions 52 are, for example, substantially uniform in the depth direction Z. Balanced charge is generally maintained between the n-type column regions 51 and the p-type column regions 52 adjacent to each other. The drift resistance may be adjusted by the dopant concentration of the n-type column regions 51.

The n-type column regions 51 and the p-type column regions 52 are orthogonal to the gate trenches 6, whereby current paths of body diodes (BDs), which are formed in each of the unit cells 10a adjacent to each other in the second direction Y, are connected linearly in the second direction Y by the n-type column regions 51. Therefore, forward voltage Vf of the body diodes in the unit cells 10a is reduced, whereby the body diode is less likely to operate thereby enabling operation of a parasitic bipolar junction transistor (BJT) to be suppressed.

The body diodes are parasitic diodes formed by the pn junctions (the main junctions) between the p⁺⁺-type contact regions 5, the p-type base region 3, the first and second p⁺-type regions 31 and 32, the n-type current spreading regions 33, the n-type column regions 51, and the n⁺-type drain region 1. The parasitic BJT is a parasitic npn bipolar junction transistor in which the n⁺-type source regions 4 constitutes an emitter or a collector, the n-type current spreading regions 33, the n-type column regions 51, and the n⁺-type drain region 1 constitute a collector or an emitter, and therebetween, the p-type base region 3 and the first and second p⁺-type regions 31 and 32 constitute a base.

A method of manufacturing the silicon carbide semiconductor device 50 according to the second embodiment may be implemented by setting the arrangement of the n-type column regions 51 and the p-type column regions 52 of the parallel pn layer 53 as described above in the method of manufacturing the silicon carbide semiconductor device 10 according to the first embodiment.

As described above, according to the second embodiment, effects similar to those of the first embodiment may be achieved even in a case where the n-type column regions and p-type column regions in the parallel pn layer are arranged in the striped pattern orthogonal to the gate trenches, as viewed from the front surface of the semiconductor substrate.

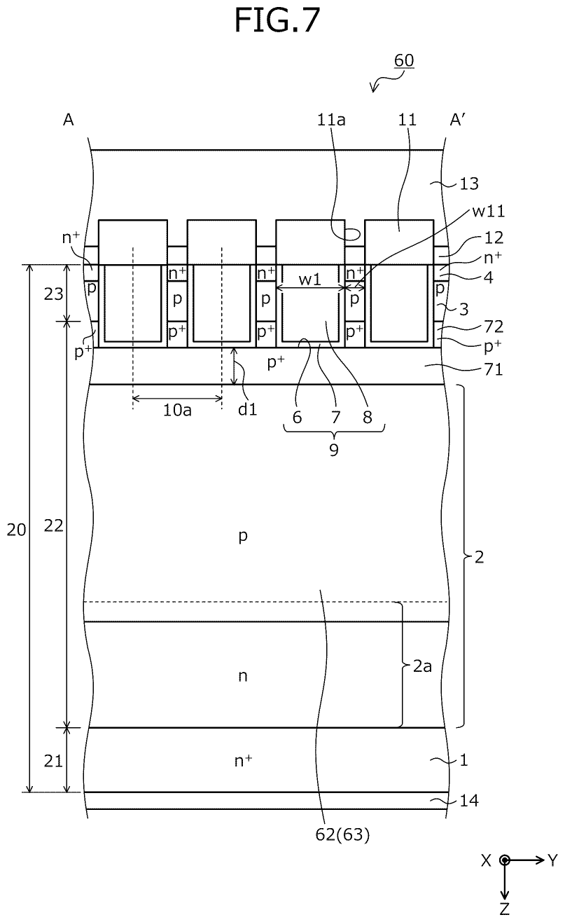

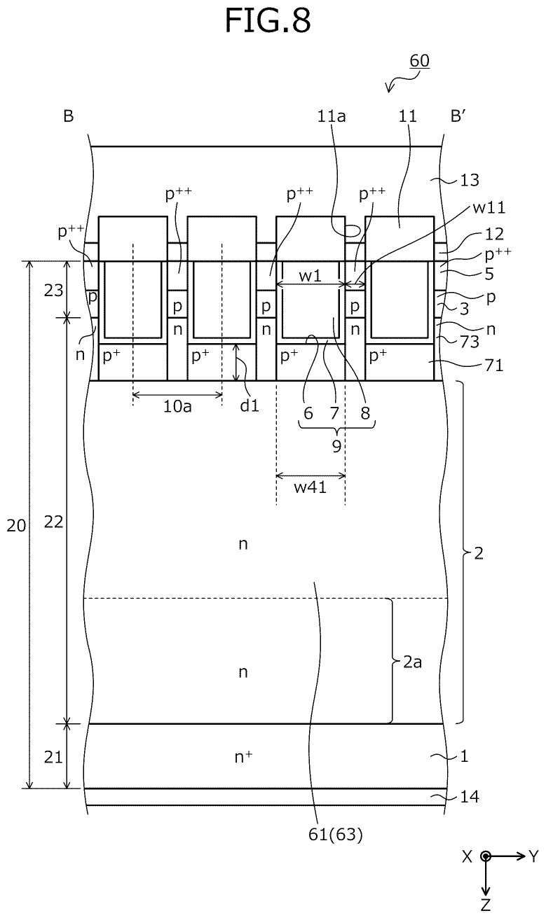

A silicon carbide semiconductor device according to a third embodiment for solving the above problems is described. FIGS. 7, 8, and 9 are cross-sectional views depicting the structure of a silicon carbide semiconductor device according to a third embodiment. A layout of the n⁺-type source regions 4, the p⁺⁺-type contact regions 5, and the MOS gates 9 of a silicon carbide semiconductor device 60 according to the third embodiment, as viewed from the front surface of the semiconductor substrate 20, is the same as that of the first embodiment (see FIG. 1). FIGS. 7 to 9 respectively depict the structure along cutting lines A-A′, B-B′, and C-C′ in FIG. 1.

The silicon carbide semiconductor device 60 according to the third embodiment differs from the silicon carbide semiconductor device 50 according to the second embodiment (see FIGS. 4 to 6) in that n-type column regions 61 of the parallel pn layer 63 are arranged directly below the p⁺⁺-type contact regions 5. In the third embodiment, n-type current spreading regions 73 and the n-type column regions 61 of the parallel pn layer 63 are arranged directly below the p⁺⁺-type contact regions 5. The first and second p⁺-type regions 71, 72, and the p-type column regions 62 of the parallel pn layer 63 are arranged directly below the n⁺-type source regions 4.

The first and second p⁺-type regions 71, 72 and the n-type current spreading regions 73 are each selectively provided between the p-type base region 3 and the parallel pn layer 63. The first p⁺-type region 71 is provided at positions facing the bottoms of the gate trenches 6 and is closer to the n⁺-type drain region 1 than are the bottoms of the gate trenches 6, the first p⁺-type region 71 is apart from the p-type base region 3. The first p⁺-type region 71 extends in the first direction X with a predetermined width w41; the first p⁺-type region 71 has a length substantially a same as the longitudinal length of the gate trenches 6. The width w41, in the second direction Y, of each of the portions of the first p⁺-type region 71 directly below the gate trenches 6 is not more than the width w1 of each of the gate trenches 6 in the second direction Y, and is wider than the Fin width w11.

The portions of the first p⁺-type region 71 directly below the gate trenches 6 and adjacent to each other extend directly below the n⁺-type source regions 4 and are connected to each other. The first p⁺-type region 71 is not disposed directly below the p⁺⁺-type contact regions 5. That is, the first p⁺-type region 71 is disposed facing, in the depth direction Z, the bottoms of the gate trenches 6 and the n⁺-type source regions 4, in the ladder shape as viewed from the front surface of the semiconductor substrate 20. The first p⁺-type region 71 has an upper surface in contact with the second p⁺-type regions 72 and the gate insulating films 7 along the bottoms of the gate trenches 6.

Each of the portions of the first p⁺-type region 71 directly below the n⁺-type source regions 4 has a lower surface in contact with the p-type column regions 62. A width w42, in the first direction X, of each of the portions of the first p⁺-type region 71 directly below the n⁺-type source regions 4 is, for example, narrower than the interval w32 between the p⁺⁺-type contact regions 5 adjacent to each other in the first direction X (w42<w32). An interval w43 at which the portions of the first p⁺-type region 71 directly below the n⁺-type source regions 4 are arranged in the first direction X is, for example, wider than the width w31 of each of the p⁺⁺-type contact regions 5 in the first direction X (w43>w31).

Between the gate trenches 6 adjacent to each other, the second p⁺-type regions 72 are disposed between and in contact with the p-type base region 3 and the first p⁺-type region 71. That is, the second p⁺-type regions 72 are disposed only directly below the n⁺-type source regions 4 and are interspersed in the first direction X. The second p⁺-type regions 72 are not disposed directly below the p⁺⁺-type contact regions 5. The second p⁺-type regions 72 are arranged in the first direction X with substantially the same width and at the substantially the same interval as the portions of the first p⁺-type region 71 directly below the n⁺-type source regions 4.

The n-type current spreading regions 73 are disposed directly below the p⁺⁺-type contact regions 5 and terminate directly below the n⁺-type source regions 4 adjacent to the p⁺⁺-type contact regions 5. The configuration of the first and second p⁺-type regions 71, 72, and the n-type current spreading regions 73 except for the arrangement of the portions thereof directly below the p⁺⁺-type contact regions 5 and the portions thereof directly below the n⁺-type source regions 4 is the same as the first and second p⁺-type regions 31, 32 and the n-type current spreading regions 33 in the second embodiment.

Directly below the p⁺⁺-type contact regions 5, the n-type column regions 61 extend linearly in the second direction Y and are in contact with the first p⁺-type region 71 and the n-type current spreading regions 73. The p-type column regions 62 are apart from the n-type current spreading regions 73.

The width Wn3 of each of the n-type column regions 61 in the lateral direction (the first direction X) is wider than the width w42, in the first direction X, of the portions of the first p⁺-type region 71 directly below the n⁺-type source regions 4 (Wn3>w42). A width Wp3 of each of the p-type column regions 62 in the lateral direction (the first direction X) is narrower than the width w42, in the first direction X, of each of the portions of the first p⁺-type region 71 directly below the n⁺-type source regions 4 and is wider than the Fin width w11 (w42>Wp3>w11).

The respective widths Wn3 and Wp3 the n-type column regions 61 and the p-type column regions 62 in the lateral direction are substantially uniform in the depth direction Z. Respective dopant concentrations of the n-type column regions 61 and the p-type column regions 62 are, for example, substantially uniform in the depth direction Z. Balanced charge is generally maintained between the n-type column regions 61 and the p-type column regions 62 adjacent to each other. The drift resistance may be adjusted by the dopant concentration of the n-type column regions 61.

Directly below the n⁺-type source regions 4, the p-type column regions 62 extend linearly in the second direction Y and thereby prevent blockage of the current path (the connection point between the n-type current spreading regions 73 and the n-type column regions 61) due to misalignment of the p-type column regions 62 in the second direction Y. An effect obtained by orthogonally intersecting the n-type column regions 61 and the p-type column regions 62 with the gate trenches 6 is the same as that in the second embodiment (suppression of the parasitic BJT operation).

A method of manufacturing the silicon carbide semiconductor device 60 according to the third embodiment may be implemented by setting the arrangement of the n-type column regions 61 and p-type column regions 62 of the parallel pn layer 63 and the arrangement of the first and second p⁺-type regions 71, 72, and the n-type current spreading regions 73 as described above in the method of manufacturing the silicon carbide semiconductor device 50 according to the second embodiment.

As described above, according to the third embodiment, even in a case where the n-type column regions and the p-type column regions of the parallel pn layer are arranged in a striped pattern orthogonal to the gate trenches as viewed from the front surface of the semiconductor substrate, effects similar to those of the first embodiment may be obtained. According to the third embodiment, even in a case where the p-type column regions of the parallel pn layer are arranged directly below the n⁺-type source regions, effects similar to those of the second embodiment may be obtained.

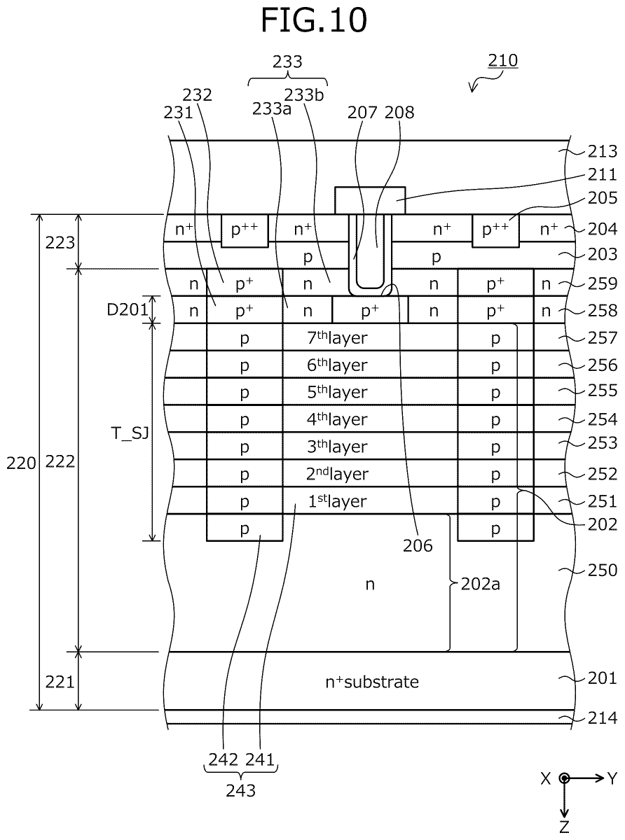

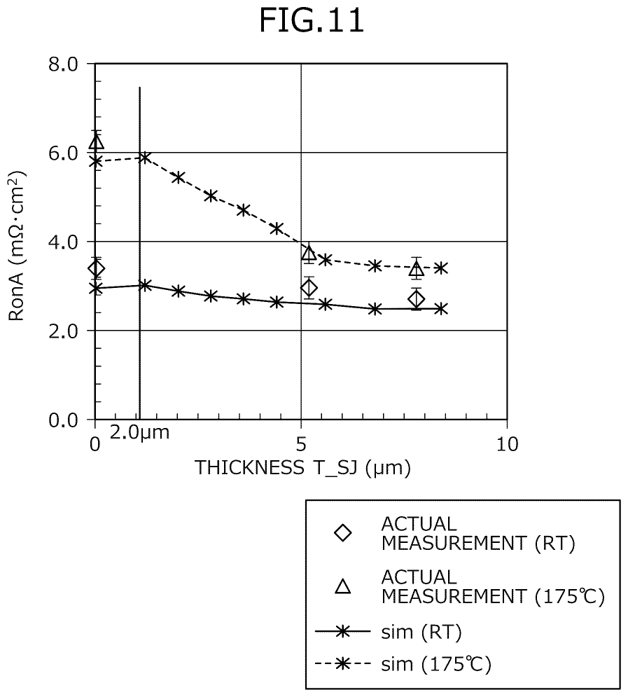

A relationship between the thickness Lsj and on-resistance RonA in the parallel pn layer 43 of the silicon carbide semiconductor device 10 (see FIGS. 2 and 3) according to the first embodiment was verified. The electrical characteristics of the parallel pn layer are the same regardless of the presence or absence of the FinFET structure. Thus, the electrical characteristics of the parallel pn layer were verified using a normal SiC-MOSFET (hereinafter referred to as a comparison example) without the FinFET structure. FIG. 10 is a cross-sectional view depicting the structure of the comparison example. FIG. 11 is a characteristic diagram depicting results of verifying on-resistance characteristics of the comparison example. In FIG. 11, a horizontal axis is the thickness T_SJ [μm] of a parallel pn layer 243 of the comparison example and a vertical axis is the on-resistance RonA [mΩ·cm²] of the comparison example.

A comparison example 210 depicted in FIG. 10 is a vertical MOSFET with a SJ structure in which a drift layer 202 is configured as the parallel pn layer 243, and has a normal unit cell that is not the FinFET structure, with a relatively wide width between gate trenches 206 adjacent to each other. The comparison example 210 differs from the silicon carbide semiconductor device 10 according to the first embodiment in that the width between the adjacent gate trenches 206 is relatively wide, and in the layout of first and second p⁺-type regions 231 and 232 as viewed from a front surface of a semiconductor substrate 220 thereof. Specifically, the semiconductor substrate 220 is formed by growing epitaxial layers 222 and 223 constituting the drift layer 202 and a p-type base region 203, in this order, on an n⁺-type starting substrate 221 constituting an n⁺-type drain region 201.

The drift layer 202 is in contact with the n⁺-type drain region 201, between the p-type base region 203 and the n⁺-type drain region 201. A portion of the drift layer 202 facing n⁺-type source regions 204 is the parallel pn layer 243. Similar to the first embodiment, in the parallel pn layer 243, n-type column regions 241 and p-type column regions 242 are adjacent to one another and repeatedly alternate with one another in the second direction Y. Similar to the first embodiment, the n-type column regions 241 and the p-type column regions 242 extend in a striped pattern in the first direction X. A portion of the drift layer 202 between the parallel pn layer 243 and the n⁺-type drain region 201 is an n-type buffer region 202a. T_SJ, the thickness of the parallel pn layer 243, is determined by the length of the p-type column regions 242 in the depth direction Z.

The parallel pn layer 243 was formed in the n-type epitaxial layer 222 by the multi-stage epitaxial method. As the n-type epitaxial layer 222, n-type layers 250 to 259 were grown by epitaxy in multi-stages. The p-type regions constituting the p-type column regions 242 are formed adjacent to one another in the depth direction Z in the n-type layers 250 to 257. A portion of the n-type layer 250 excluding the p-type column regions 242 constitutes the n-type buffer region 202a. Portions of the n-type layers (1st layer to 7th layer) 251 to 257 excluding the p-type column regions 242 constitute the n-type column regions 241. A thickness of the n-type layer 250 corresponds to the thickness of the n- type buffer region 202a and is thicker than the thickness of the n-type layer 251. Respective thicknesses of n-type layers 251 to 259 are the same.

A trench gate structure configured by the p-type base region 203, n⁺-type source regions 204, p⁺⁺-type contact regions 205, the gate trenches 206, gate insulating films 207, and gate electrodes 208 is disposed in the semiconductor substrate 220, at the front surface thereof (main surface having the p-type epitaxial layer 223). The n⁺-type source regions 204 and the p⁺⁺-type contact regions 205 are diffused regions formed by ion implantation in surface regions of the semiconductor substrate 220, at the front surface thereof (surface regions of the p-type epitaxial layer 223). The n⁺-type source regions 204 and the p⁺⁺-type contact regions 205 are selectively disposed between the front surface of the semiconductor substrate 220 and the p-type base region 203 and are in contact with the p-type base region 203.

The n⁺-type source regions 204 and the p⁺⁺-type contact regions 205 are in ohmic contact with a source electrode 213 on the front surface of the semiconductor substrate 220. The p-type base region 203 and the n⁺-type source regions 204 extend, along sidewalls of the gate trenches 206, in the first direction X and have a length substantially equal to a longitudinal length of the gate trenches 206. The p-type base region 203 and the n⁺-type source regions 204 are in contact with the gate insulating films 207 along the sidewalls of the gate trenches 206. At the sidewalls of each gate trenches 206, a different one of the n⁺-type source regions 204 is in contact with the gate insulating film 207 of said each of the gate trenches 206. The p⁺⁺-type contact regions 205 are disposed in substantially a center between the gate trenches 206 adjacent to each other and are apart from the gate trenches 206.

Each of the gate trenches 206 extends in a stripe shape in the first direction X, similar to the first embodiment. The gate trenches 206 penetrate, in the depth direction Z, the n⁺-type source regions 204 and the p-type base region 203 from the front surface of the semiconductor substrate 220 and reach the first p⁺-type regions 231. Inside the gate trenches 206, the gate electrodes 208 are disposed via the gate insulating films 207, respectively. The gate electrodes 208 are electrically insulated from the source electrode 213 by an interlayer insulating film 211. A drain electrode 214 is provided at a back surface of the semiconductor substrate 220 and is electrically connected to the n⁺-type drain region 201. The first and second p⁺-type regions 231 and 232 and n-type current spreading regions 233 are diffused regions formed by ion implantation in upper layers (n-type layers closest to the n⁺-type source regions 204) 258, 259 of the n-type epitaxial layer 222, the first and second p⁺-type regions 231 and 232 and the n-type current spreading regions 233 each being selectively disposed between the p-type base region 203 and the drift region 202.

The first p⁺-type regions 231 are selectively provided apart from the p-type base region 203, at deep positions closer to the n⁺-type drain region than are the bottoms of the gate trenches 206. At positions facing the bottoms of the gate trenches 206 and at portions substantially in the center between the gate trenches 206 adjacent to each other (i.e. directly below the p⁺⁺-type contact regions 205), the first p⁺-type regions 231 extend in the first direction X and have substantially the same length as the longitudinal length of the gate trenches 6. The first p⁺-type regions 231 adjacent to each other are partially connected to each other at a portion not depicted. The first p⁺-type regions 231 directly below the gate trenches 206 are in contact with the gate insulating films 207 along the bottom of each of the gate trenches 206. Each of the first p⁺-type regions 231 directly below the gate trenches 206 has a lower surface in contact with the n-type column regions 241. The first p⁺-type regions 231 directly below the p⁺⁺-type contact regions 205 are provided apart from the gate trenches 206. Each of the first p⁺-type regions 231 directly below the p⁺⁺-type contact regions 205 has a lower surface in contact with the p-type column regions 242.

The second p⁺-type regions 232 are disposed between the gate trenches 206 adjacent to each other; the second p⁺-type regions 232 are apart from the gate trenches 206 and in contact with the p-type base region 203. The second p⁺-type regions 232 extend between the first p⁺-type regions 231 directly below the p⁺⁺-type contact regions 205 and the p-type base region 203, in the first direction X and have a length substantially equal to the longitudinal length of the gate trenches 6. The second p⁺-type regions 232 electrically connect the first p⁺-type regions 231 and the p-type base region 203. Each of the n-type current spreading regions 233 has an upper surface in contact with the p-type base region 203 and a lower surface in contact with the n-type column regions 241; the n-type current spreading regions 233 are in contact with the first and second p⁺-type regions 231 and 232 and the gate insulating films 207 along the sidewalls of the gate trenches 206, in the second direction Y. Each of the n-type current spreading regions 233 is divided into an upper part 233a and a lower part 233b formed in multiple stages.

FIG. 11 depicts, for this comparison example 210, results of actual measurement of the on-resistance RonA by variously changing the thickness T_SJ of the parallel pn layer 243 (actual measurement), and the on-resistance RonA (sim) with respect to the thickness T_SJ of the parallel pn layer 243, simulated based on the actual measurement results. The thickness T_SJ of the parallel pn layer 243 corresponds to the thickness Lsj of the parallel pn layer 43 of the silicon carbide semiconductor device 10 according to the first embodiment (see FIGS. 2 and 3). FIG. 11 depicts a sample of the comparison example 210 operated at room temperature (RT, substantially 25 degrees C.) and a sample of the comparison example 210 operated in a temperature environment of 175 degrees C.

The results depicted in FIG. 11 confirm that the thickness T_SJ of the parallel pn layer 243 is 2 μm or more, and that the effect of reducing the on-resistance RonA increases the greater the thickness T_SJ of the parallel pn layer 243 is increased. A depth D201 of the first p⁺-type region 231 was set to 0.5 μm. Therefore, the thickness T_SJ of the parallel pn layer 243 is preferably four times or more a depth D201 of the first p⁺-type region 231. Thus, the thickness Lsj of the parallel pn layer 43 of the silicon carbide semiconductor device 10 (see FIGS. 2 and 3) according to the first embodiment is confirmed to be at least 2 μm and preferably, at least four times the depth d1 of the first p⁺-type region 31.

While not depicted, the parallel pn layers 53, 63 of the silicon carbide semiconductor devices 50 and 60 according to the second and third embodiments have the same characteristics as those depicted in FIG. 11.

As described above, the present disclosure is not limited to the above-mentioned embodiments, and various modifications may be made without departing from the spirit of the present disclosure. For example, instead of forming the n⁺-type source regions by ion implantation, the n⁺-type source regions may be formed by an n⁺-type epitaxial layer. In this case, the surface of the n⁺-type epitaxial layer constituting the n⁺-type source regions is the front surface of the semiconductor substrate. Although the first conductivity type is an n-type and the second conductivity type is a p-type in each embodiment, the present disclosure is similarly implemented when the first conductivity type is a p-type and the second conductivity type is an n-type.

According to the silicon carbide semiconductor device according to the present disclosure, the silicon carbide semiconductor device has the trench gate structure in which unit cells of the FinFET structure are arranged and achieves an effect of enabling reduction of the on-resistance.

As described above, the silicon carbide semiconductor device according to the present disclosure is useful for power semiconductor devices used in power converting equipment, power supply devices for various industrial machines, and the like.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A silicon carbide semiconductor device comprising:
a semiconductor substrate containing silicon carbide, and having a first main surface and a second main surface opposite to each other;
a parallel pn layer provided in the semiconductor substrate, the parallel pn layer having a plurality of first-conductivity-type regions of a first conductivity type and a plurality of second-conductivity-type regions of a second conductivity type, disposed repeatedly alternating with each other;
a first semiconductor region of the second conductivity type, provided in the semiconductor substrate between the first main surface of the semiconductor substrate and the parallel pn layer;
a plurality of second semiconductor regions of the first conductivity type, selectively provided in the semiconductor substrate between the first main surface of the semiconductor substrate and the first semiconductor region;
a plurality of third semiconductor regions of the second conductivity type, selectively disposed in the semiconductor substrate between the first main surface of the semiconductor substrate and the first semiconductor region, and having a dopant concentration higher than a dopant concentration of the first semiconductor region;
a plurality of gate trenches penetrating, in a depth direction of the silicon carbide semiconductor device, the plurality of third semiconductor regions, the plurality of second semiconductor regions, and the first semiconductor region;
a first high concentration region of the second conductivity type, provided between the first semiconductor region and the parallel pn layer and having a dopant concentration higher than the dopant concentration of the first semiconductor region, the first high concentration region having a plurality of portions selectively disposed in contact with the parallel pn layer at positions respectively facing bottoms of the plurality of gate trenches;
a plurality of gate electrodes provided in the plurality of gate trenches via a plurality of gate insulating films, respectively;
a first electrode electrically connected to the plurality of third semiconductor regions, the plurality of second semiconductor regions, the first semiconductor region, and the first high concentration region; and
a second electrode provided at the second main surface of the semiconductor substrate, wherein
the plurality of gate trenches have, between any adjacent two thereof, a portion of the first semiconductor region therein;
the silicon carbide semiconductor device has a double gate structure in which, for each adjacent two of the plurality of gate trenches, a channel is formed over an entire area of the portion of the first semiconductor region therebetween, and is sandwiched by said each adjacent two of the plurality of gate trenches;
each of the plurality of first-conductivity-type regions has a width greater than a width of each of the plurality of portions of the first high concentration region; and
each of the plurality of second-conductivity-type regions has a width smaller than the width of each of the plurality of portions of the first high concentration region and greater than a distance between any adjacent two of the plurality of gate trenches.

2. The silicon carbide semiconductor device according to claim 1, wherein
the plurality of gate trenches extends linearly in a first direction parallel to the first main surface of the semiconductor substrate, so as to be arranged adjacent to one another in a second direction, which is parallel to the first main surface of the semiconductor substrate and orthogonal to the first direction, in a striped pattern, and
the plurality of first-conductivity-type regions and the plurality of second-conductivity-type regions extend linearly in the first direction and repeatedly alternate with each other in the second direction.

3. The silicon carbide semiconductor device according to claim 2, wherein
each of the plurality of second-conductivity-type regions faces a bottom of every other one of the plurality of gate trenches.

4. The silicon carbide semiconductor device according to claim 1, wherein
the plurality of gate trenches extends linearly in a first direction parallel to the first main surface of the semiconductor substrate, so as to be arranged adjacent to one another in a second direction, which is parallel to the first main surface of the semiconductor substrate and orthogonal to the first direction, in a striped pattern, and
the plurality of first-conductivity-type regions and the plurality of second-conductivity-type regions extend linearly in the second direction and repeatedly alternate with each other in the first direction.

5. The silicon carbide semiconductor device according to claim 4, wherein
a subset of the plurality of second semiconductor regions and a subset of the plurality of third semiconductor regions repeatedly alternate with each other in the first direction,
the first high concentration region has a plurality of connection portions connecting the plurality of portions at positions facing the plurality of third semiconductor regions in the depth direction, and
the plurality of second-conductivity-type regions is adjacent to the plurality of connection portions in the depth direction and extends linearly in the second direction.

6. The silicon carbide semiconductor device according to claim 4, wherein
a subset of the plurality of second semiconductor regions and a subset of the plurality of third semiconductor regions repeatedly alternate with each other in the first direction,
the first high concentration region has a plurality of connection portions connecting the plurality of portions at positions facing the plurality of second semiconductor regions in the depth direction, and
the plurality of second-conductivity-type regions is adjacent to the plurality of connection portions in the depth direction and extends linearly in the second direction.

7. The silicon carbide semiconductor device according to claim 1, wherein
the parallel pn layer has a thickness of 2 μm or more.

8. The silicon carbide semiconductor device according to claim 1, wherein
the parallel pn layer has a thickness of at least four times a thickness of the first high concentration region.

9. The silicon carbide semiconductor device according to claim 1, comprising:
a fourth semiconductor region of the first conductivity type, provided in the semiconductor substrate between the first semiconductor region and the parallel pn layer, the fourth semiconductor region being in contact with the first semiconductor region and the first high concentration region and having a dopant concentration at least equal to a dopant concentration of the first-conductivity-type regions, and
the fourth semiconductor region and the first high concentration region terminate at a same depth.

10. The silicon carbide semiconductor device according to claim 1, wherein
the first high concentration region has a plurality of connection portions connecting the plurality of portions at positions each between adjacent two of the plurality of gate trenches, and
the silicon carbide semiconductor device comprises a second high concentration region of the second conductivity type, each provided between adjacent two of the plurality of gate trenches, the second high concentration region being between and in contact with the first semiconductor region and each of the plurality of connection portions of the first high concentration region, the second high concentration region having a dopant concentration higher than a dopant concentration of the plurality of second semiconductor regions.
